(19) United States
(12) Patent Application Publication
(10) Pub. No.: US 2026/0340800 A1
(43) Pub. Date: Oct. 29, 2026

(54) DIMENSION MEASUREMENT DEVICE, DIMENSION MEASUREMENT METHOD, AND DIMENSION MEASUREMENT SYSTEM

(71) Applicant: HITACHI HIGH-TECH CORPORATION, Minato-ku, Tokyo (JP)

(72) Inventors: Yutaka OKUYAMA, Tokyo (JP); Takeshi OHMORI, Tokyo (JP)

(21) Appl. No.: 19/103,709

(22) PCT Filed: Sep. 20, 2023
(86) PCT No.: PCT/JP2023/034044

§ 371 Date: Feb. 13, 2025

(51) Int. Cl. G06T 7/00; G01N 23/04; G01N 23/06; G01N 23/2251; G06T 7/60; G06V 10/24; G06V 10/26; G06V 10/44; G06V 10/764; G06V 10/774; G06V 10/82

(52) U.S. Cl. CPC G06T 7/0004; G01N 23/04; G01N 23/06; G01N 23/2251; G06T 7/60; G06V 10/242; G06V 10/26; G06V 10/44; G06V 10/764; G01N 2223/401; G01N 2223/6116; G06T 2207/10061; G06T 2207/20081; G06T 2207/20084; G06T 2207/20101; G06T 2207/30148; G06V 10/774; G06V 10/82

(57) ABSTRACT

A dimension measurement device according to one aspect of the present disclosure is a dimension measurement device for measuring, based on a cross-sectional image of a semiconductor device having a repeating pattern, a dimension of the semiconductor device. The dimension measurement device includes: a processor; and a memory. The memory stores a dimension measurement program causing the processor to function as a training unit in which a semantic segmentation model is implemented, an inference unit configured to determine, based on a segmentation image output by the training unit in response to an input image, contours classified using label information of the segmentation image, and to determine, based on the contours, a feature point satisfying a predetermined criterion or an opposing distance between contours, and a dimension measurement unit configured to measure a dimension of a predetermined measurement portion using data determined by the inference unit.

### TECHNICAL FIELD

The present invention relates to a dimension measurement device, a dimension measurement method, and a dimension measurement system.

### BACKGROUND ART

In recent years, in order to improve the performance of a semiconductor device, introduction of a new material into a semiconductor device and the three-dimensionalization and complexity of a structure of the semiconductor device have progressed. In the current leading-edge semiconductor device processing, the accuracy of a nanometer level is required. In the process development, after processing using a processing device such as an etching device, a cross-sectional image of a sample is captured, a dimension of a necessary portion is measured, the processing results are fed back to process construction, and the above steps are repeated. However, in the dimension measurement, the measurement performed manually has reached the limit thereof with the complexity of a structure and an increase in the number of measurement portions per image. Further, even in an image in which line/space unit patterns are repeated, each individual pattern is measured one by one. Therefore, the manual measurement has a problem in that statistical values of measurement values include not only process variations but also human errors.

To solve the problem, PTL 1 discloses an automatic measurement method and an automatic measurement system using an image recognition model based on deep learning. In PTL 1, using a first image recognition model for extracting a boundary between a processing structure and a background and/or a boundary of an interface between dissimilar materials over the entire cross-sectional image, and a second image recognition model for outputting information for dividing the boundaries extending over the entire cross-sectional image obtained from the first image recognition model for each unit pattern constituting a repeating pattern, coordinates of a plurality of feature points defined in advance for each unit pattern are determined, and a dimension defined as a distance between two predetermined points among the plurality of feature points is measured. In this method, an image (segmentation image) obtained by performing labeling for each region on a cross-sectional image is output by a first semantic segmentation model, a coordinate at which each of the unit patterns constituting the repeating pattern in the cross-sectional image is positioned is output by a second object detection model, and a dimension is determined by searching for coordinates of an end point necessary for measurement on the labeled image clipped using the coordinates at which the unit patterns are respectively positioned, according to a post-processing script in the dimension measurement unit.

### CITATION LIST

### Patent Literature

PTL 1: JP6872670B

### SUMMARY OF INVENTION

### Technical Problem

In the method according to PTL 1, when it is desired to change or add a measurement n portion, correction of a post-processing script is necessary. Further, when the object to be measured is to be changed from a line side to a space side or vice versa, it is necessary to recreate annotation data for the object detection model and retrain the model. These operations are difficult for a general user of the measurement system, and there is room for improvement because it takes time to create the annotation data and retrain the model even if an engineer performs processing.

Therefore, an object of the invention is to implement dimension measurement of any portion without performing system correction.

### Solution to Problem

In order to solve the above problems, a dimension measurement device according to one aspect of the present disclosure is a dimension measurement device for measuring, based on a cross-sectional image of a semiconductor device having a repeating pattern, a dimension of the semiconductor device. The dimension measurement device includes: a processor; and a memory. The memory stores a dimension measurement program causing the processor to function as a training unit in which a semantic segmentation model is implemented, an inference unit configured to determine, based on a segmentation image output by the training unit in response to an input image, contours classified using label information of the segmentation image, and to determine, based on the contours, a feature point satisfying a predetermined criterion or an opposing distance between contours, and a dimension measurement unit configured to measure a dimension of a predetermined measurement portion using data determined by the inference unit.

### Advantageous Effects of Invention

According to the invention, it is possible to implement dimension measurement of any portion without performing system correction. Problems, configurations, and effects other than those described above will be clarified by descriptions of the following embodiments.

### BRIEF DESCRIPTION OF DRAWINGS

FIG. 1 is a diagram showing an example of a configuration of a semiconductor manufacturing system.

FIG. 2 is a diagram showing an internal configuration example of a server.

FIG. 3 is a diagram showing an example of a semantic segmentation model.

FIG. 4 is an example of a cross-sectional image which is input data.

FIG. 5 is a diagram showing an example of a segmentation image which is annotation data included in a training data set.

FIG. 6 is a table showing a correspondence relation among a label name, a label number, and a color in annotation data used for training the semantic segmentation model.

FIG. 7 is a diagram showing contours obtained from a segmentation image in FIG. 6.

FIG. 8 is a diagram showing definitions of six types of feature points extracted from contours divided in Embodiment 1.

FIG. 9 is a diagram showing a method of designating a measurement portion in Embodiment 1.

FIG. 10 is a flowchart showing an example of a processing procedure in a dimension measurement system.

FIG. 11 is a diagram showing an example of a GUI screen displayed during training of a model.

FIG. 12 is a diagram showing an example of a GUI screen displayed in an inference and measurement step.

FIG. 13 is a diagram showing an example of measurement results.

FIG. 14 is a diagram showing an opposing distance between contours extracted from contours divided in Embodiment 2.

FIG. 15 is a diagram showing a method of designating a measurement portion.

FIG. 16 is a diagram showing an example of measurement results.

FIG. 17 is a diagram showing an example of profile display results.

FIG. 18 is a diagram showing an example of a GUI screen displayed in the inference and measurement step in Embodiment 2.

### DESCRIPTION OF EMBODIMENTS

In the present disclosure, an image recognition model is used to measure, based on a cross-sectional image of a semiconductor device having a repeating pattern, a dimension of the semiconductor device. The term “semiconductor device” as used herein includes not only a finished product but also a semiconductor device in the middle of processing. It does not matter whether the semiconductor device is in the form of a wafer or in the form of individually separated chips. Specifically, the image recognition model is a semantic segmentation model for dividing a cross-sectional image into regions. By obtaining a classified contour from a segmentation image labeled for each region which is an inference result of the image recognition model and converting the contour data into a format that facilitates dimension measurement, it is possible to automatically measure a predetermined dimension value from the cross-sectional image without correction of the system during measurement.

Hereinafter, embodiments of the present disclosure will be described with reference to the accompanying drawings.

### Embodiment 1

In a dimension measurement system of the present embodiment, a training data set of the semantic segmentation model, which is an image recognition model, includes a cross-sectional scanning electron microscope (SEM) image which is image data of a dimension measurement object, and a segmentation image which is annotation data.

In a preliminary training step, a semantic segmentation model is trained. A cross-sectional SEM image, which is input data, and a segmentation image are given to the semantic segmentation model as training data, and the semantic segmentation model is caused to learn a region shape.

In the inference step, a segmentation image is obtained, based on the trained semantic segmentation model, from a cross-sectional SEM image to be measured, a contour is determined and divided based on the obtained segmentation image, the contour data is converted into a format that facilitates dimension measurement, and data is stored. Specifically, classified contours are determined based on a segmentation image obtained by performing inference on an input image by using the trained semantic segmentation model, using label information of the segmentation image, and a point satisfying a predetermined criterion or an opposing distance between contours is determined based on the classified contours. Details will be described below.

A measurement step is a step in which a dimension of a predetermined measurement portion is measured using the data determined in the inference step. Specifically, data related to a measurement portion designated by a user is read and converted into a dimension, so that a desired dimension value is automatically measured without correction of the system.

### Configuration Example of Dimension Measurement System

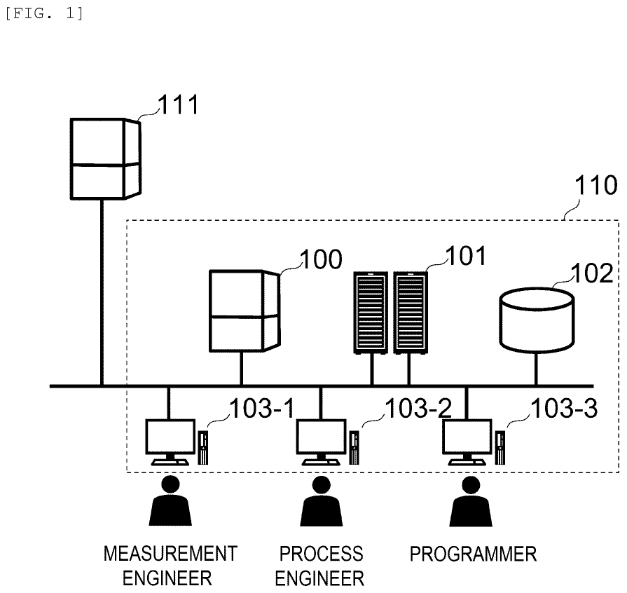

First, a configuration of the dimension measurement system will be described. FIG. 1 is a diagram showing an example of a configuration of a semiconductor manufacturing system. The semiconductor manufacturing system includes a processing device 111 and a dimension measurement system 110. The dimension measurement system 110 includes an evaluation device 100, a server 101, a database 102, and one or more input and output devices 103, which are connected to one another via a network. The processing device 111 and the dimension measurement system 110 are connected to each other via a network, and the present disclosure can be applied even when they are not connected to each other. When connected to the network, the processing device 111 transmits processing condition data and the like to the evaluation device 100 via the network.

The input and output device 103 is a terminal equipped with a display and a keyboard, or a PC or tablet with a built-in storage medium, and is used by a system operator such as a measurement engineer who uses the evaluation device 100, a process engineer who uses the processing device 111, or a programmer who manages the server 101 and the database 102 as illustrated in the drawing. In the following description, when the term “input and output device 103” is described, the term “input and output device 103” is a generic name for an input and output device 103-1, an input and output device 103-2, and an input and output device 103-3, and is intended to be a description of features common to all input and output devices. The number of input and output devices is not limited to three.

The processing device 111 is a device that processes a semiconductor or a semiconductor device including a semiconductor. The contents of the processing by the processing device 111 are, for example, pattern processing, and include, for example, processing performed by at least any one of a wet etching device, a dry etching device, an electron beam processing device, and a laser processing device. In the following description, a case where the processing device 111 is an etching device will be described as an example.

The evaluation device 100 is a device that evaluates a semiconductor or a semiconductor device including a semiconductor. Specifically, the evaluation device 100 is a device for outputting a cross-sectional image, which is an evaluation result, for a sample obtained from a wafer processed by the processing device 111, and includes, for example, a processing dimension measurement device using an SEM, transmission electron microscope (TEM), or an optical monitor. The form of the sample obtained from the wafer may be a sample (coupon) obtained by cleaving the wafer and cutting out a part of the wafer, or the entire wafer. In addition, a lamella preparation device may be disposed in the middle of carrying the wafer from the processing device 111 to the evaluation device 100, and a part of a semiconductor or a semiconductor device may be extracted as a fragment from the device, and the extracted sample may be used as a measurement target sample.

The server 101 can be implemented by a normal computer, and an OS, a framework, a library, a program language, a model, and the like necessary for deep learning are installed therein. It is desirable that a high-performance graphics processing unit (GPU) is provided in order to perform training of a model in a short time. The training and inference of the model are performed by log-in from the input and output device 103 to the server 101.

The database 102 is an external storage device that stores processing conditions of the processing device 111 for each sample, imaging conditions of the evaluation device 100, cross-sectional images, annotation data, model parameters representing trained models, data obtained by processing contour data, measurement results, and the like.

A process engineer creates annotation data from the input and output device 103 for images obtained by the evaluation device 100 and stored in the database 102, stores the annotation data in the database 102, and also issues a command from the input and output device 103 to perform training of the model on the server 101. After the training of the model, when an image to be measured, which is obtained by the evaluation device 100, is given, inference is performed using the trained model, and data obtained by processing the segmentation image, which is an inference result, and the contour data is stored in the database 102. During the measurement, when a desired measurement portion is input, necessary data is read from the database 102, and the dimension is automatically measured. If necessary, the programmer uses the input and output device 103 to switch models.

The above operations do not necessarily need to be shared by a measurement engineer, a process engineer, and a programmer, and one system operator may independently execute each operation.

Internal Configuration Example of Server 101 on which Dimension Measurement Function is Implemented

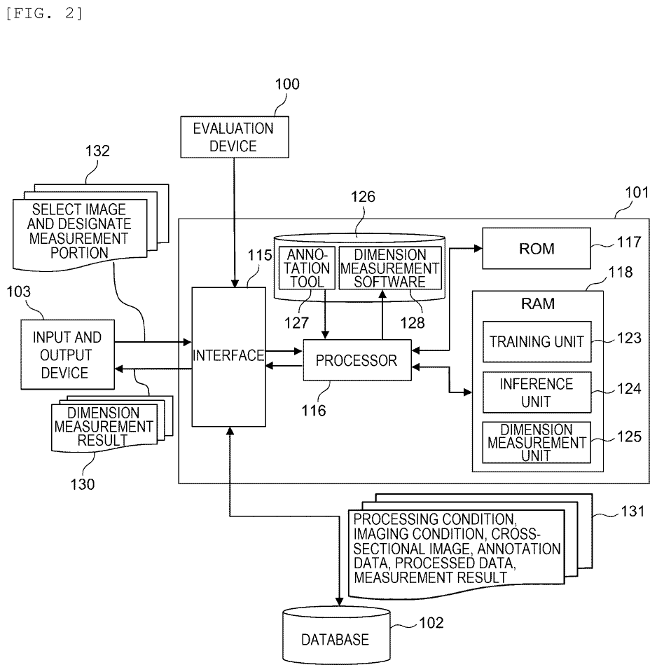

FIG. 2 is a diagram showing an internal configuration example of the server 101. The server 101 can also be referred to as a dimension measurement device that measures, based on a cross-sectional image of a semiconductor device having a repeating pattern, a dimension of the semiconductor device. The dimension measurement device includes a processor 116 and memories (117, 118, and 126), and the memory stores a dimension measurement program that causes the processor 116 to function as a training unit 123 on which a semantic segmentation model is implemented, an inference unit 124 that determines, based on a segmentation image output by the training unit 123 in response to an input image, contours classified using label information of the segmentation image, and determines, based on the classified contours, a feature point satisfying a predetermined criterion or an opposing distance between contours, and a dimension measurement unit 125 that measures a dimension of a predetermined measurement portion using the data obtained by the inference unit 124. Hereinafter, details will be described.

A housing of the server 101 stores an interface 115, the processor 116, a nonvolatile memory (ROM) 117, a volatile memory (RAM) 118, a storage 126, and the like. The input and output device 103 outputs user-designated data 132, which includes the designation of the cross-sectional image to be measured and the designation of the measurement portion, to the server 101 via the interface 115, or receives a dimension measurement result 130 outputted from the server 101. Storage data 131, which is data input to the server 101, includes image data such as a cross-sectional SEM image, annotation data (including a segmentation image and label information attached to a segmentation image), model parameters representing a trained model, processed data (segmentation image), and measurement results. The storage data 131 also includes information that defines a measurement portion, processing conditions of a semiconductor device corresponding to a measurement image, and imaging conditions of a cross-sectional SEM image. The storage data 131 is stored in the database 102 and read out when necessary. Although not shown, the input and output device 103 includes input and output devices such as a mouse for operating a GUI screen and a keyboard for inputting various setting values.

The storage 126 stores an annotation tool 127 and a dimension measurement software 128 having a dimension measurement function. The annotation tool 127 may be installed in the server 101, or may be installed in any one or all of the input and output devices 103. When the annotation tool 127 is installed in the server 101, the operation of the tool is performed by the input and output device 103. The dimension measurement software 128 is loaded into the RAM 118 as necessary. When the processor 116 executes the dimension measurement software 128, a dimension measurement function is implemented by the dimension measurement system 110.

The dimension measurement software 128 mainly includes a training unit 123, an inference unit 124, and a dimension measurement unit 125, which are incorporated in the dimension measurement software 128 in the form of software modules. FIG. 2 shows a status in which the training unit 123, the inference unit 124, and the dimension measurement unit 125 are loaded in the RAM 118. In the case of a memory, in addition to the RAM 118 in which the ROM 117 and the dimension measurement software 128 are loaded, the storage 126 that stores the dimension measurement software 128 is provided.

An example in which the server 101 is implemented by hardware has been described, but the present disclosure is not limited thereto. The functions of the server 101 may be implemented using cloud services. The database 102 is not limited to being implemented by hardware, and may be implemented by cloud services.

### Example of Semantic Segmentation Model

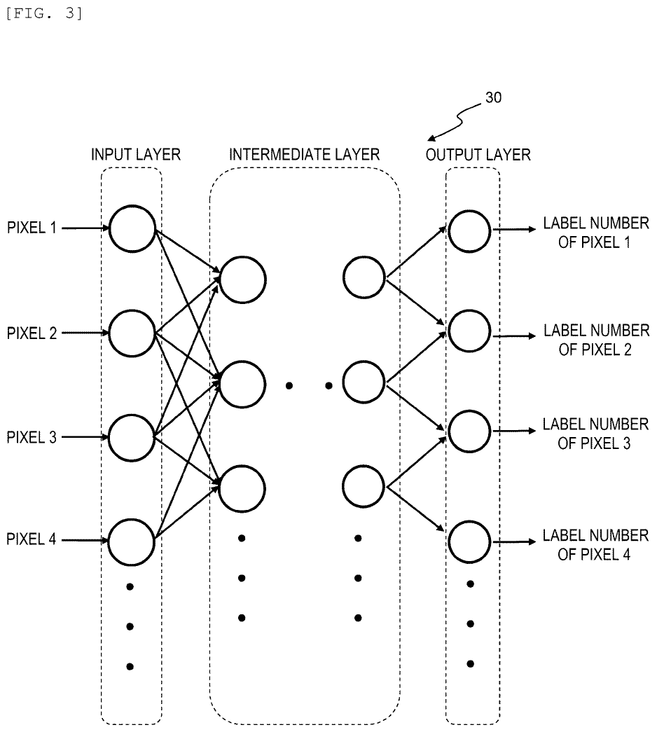

FIG. 3 is a diagram showing an example of a semantic segmentation model. The semantic segmentation model is used in the training unit 123 and the inference unit 124 of the server 101. In this example, an example in which a neural network 30 is used will be described, but the invention is not limited thereto, and a machine learning model such as a decision tree can also be used. When pixel information input to an input layer is propagated to an intermediate layer and an output layer in this order and calculated, the neural network 30 outputs a label number of a region to which each pixel belongs from the output layer. In the intermediate layer, a convolutional layer, a pooling layer, and the like are repeated to form a large number of layers. The specific layer structure varies depending on the model adopted. During training, parameters of the intermediate layer are adjusted so that an error between a label of each pixel output and correct annotation data is minimized.

During the training of the semantic segmentation model, the parameters of the intermediate layer are adjusted so that the error between the output label of each pixel and the correct annotation data is minimized. The semantic segmentation model shown in FIG. 3 is implemented in the training unit 123 shown in FIG. 2, and a main body of the dimension measurement software 128 itself is stored in the storage 126 shown in FIG. 2 The semantic segmentation model in FIG. 3 is loaded in the RAM 118 during training or inference, and is executed by the processor 116.

### Dimension Measurement Method

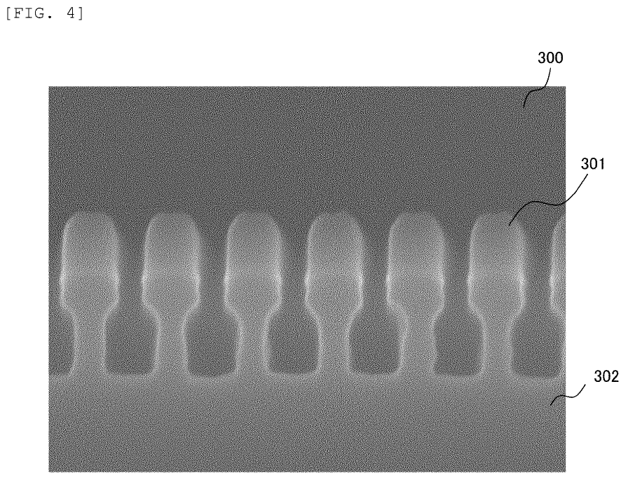

FIG. 4 is a diagram showing an example of a cross-sectional image included in the storage data 131. Specifically, FIG. 4 shows an example of a cross-sectional SEM image included in the training data set. In the case of this example, an image size is 1280 horizontal pixels and 960 vertical pixels. The sample has a trench structure in which a line/space unit pattern is repeated, with silicon dioxide as a mask 301 and silicon as a substrate 302, and thus the region in the image includes three regions, a background 300, the mask 301, and the substrate 302. In the present disclosure, an SEM image is described as an example of the cross-sectional image, but the present disclosure is not limited thereto. The cross-sectional image may also be a TEM image.

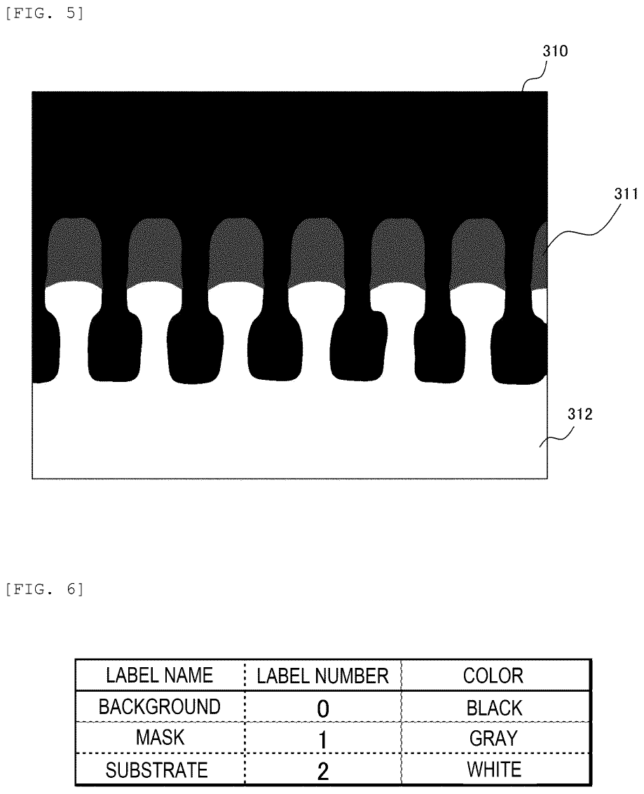

FIG. 5 is a diagram showing an example of a segmentation image which is annotation data included in a training data set. The segmentation image is created by a user using a dedicated annotation tool or using a trained semantic segmentation model on a cross-sectional SEM image which is input data to the model. The segmentation image is an image in which a label number for each region is assigned to each pixel. In the present disclosure, three regions including the background, the mask, and the substrate are extracted from the cross-sectional SEM image, and the segmentation image is divided into three regions, a background region 310, a mask region 311, and a substrate region 312.

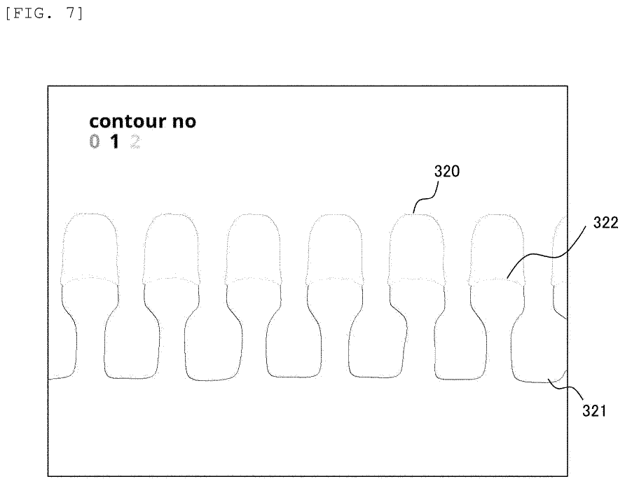

FIG. 6 is a table showing a correspondence relation among a label name, a label number, and a color in annotation data used for training the semantic segmentation model. The table shown in FIG. 6 is stored in the database 102. The label names of the three regions are “background”, “mask”, and “substrate”, the label numbers are “0”, “1”, and “2”, and the colors are “black”, “gray”, and “white”. Any label name and label number can be assigned to each label, but the label name and the label number are required to be fixed in one data set. One of the three label numbers included in the correspondence relation is assigned to each pixel included in the segmentation image.

After the model is trained using the training data set shown in FIGS. 4 and 5, when an image to be measured is input to the trained model, a segmentation image corresponding to the image is obtained as an inference result.

Thereafter, the tilt of the image is corrected. Generally, the measurement engineer captures images such that a surface of the substrate is horizontal, but the surface of the substrate may be slightly tilted because of being made horizontal manually. In the present embodiment, since the dimension is measured on the assumption that the surface of the substrate is horizontal, the image is corrected so that the surface of the substrate is horizontal. The necessary rotation angle is obtained by determining coordinate values of vertices of lines in the substrate region 312 of the segmentation image, obtaining a straight line passing through the vertices by a regression equation, and determining a tilt of the straight line. The image is rotated with a center of the image as an origin so that the surface of the substrate after the correction is horizontal. The same rotation is also performed on the original cross-sectional SEM image. Protruding parts are deleted, and missing parts are interpolated by extrapolation so that the rotated image also has the same size as the original image.

Next, the contours are determined from the corrected segmentation image. Portions where labels of two adjacent pixels are different in the segmentation image are detected as contours, and thus the contours can be classified by using a combination of the labels of the two pixels. That is, when the number of labels is N (N is an integer of 2 or more), the number M of combinations of two labels is _{N}C₂, and thus the contours can be classified into M types of contours at the maximum. In the image of FIG. 5, M=3 because N=3 (background, mask, and substrate). When numbers are assigned to the contours, the following three types of contours 0 to 2, can be distinguished. The contour 0 corresponds to a boundary between the background (label 0) and the mask (label 1), the contour 1 corresponds to a boundary between the substrate (label 0) and the background (label 2), and the contour 2 corresponds to a boundary between the mask (label 1) and the substrate (label 2).
Contour 0: the label numbers of both side regions are respectively 0 and 1.
Contour 1: the label numbers of both side regions are respectively 0 and 2.
Contour 2: the label numbers of both side regions are respectively 1 and 2.

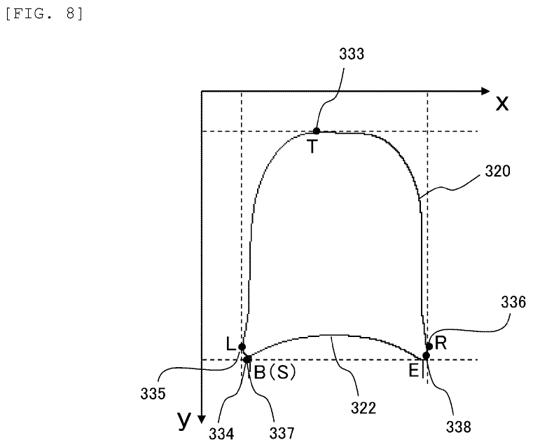

FIG. 7 is a diagram showing contours obtained from the segmentation image in FIG. 6. The contour number is automatically assigned according to the label number of an adjacent pixel. In order to clearly indicate each contour number, the contour is color-coded, and a correspondence relation between the contour number (displayed as “contour no”) and the color is printed at the upper left in the drawing. In FIG. 7, the contour 0 (320) is displayed in dark gray, the contour 1 (321) is displayed in black, and the contour 2 (322) is displayed in thin gray. When the classified contours are viewed, it is understood that each of the three types of contours is further divided into short contours arranged periodically in a horizontal direction, and the period corresponds to the period of the line/space pattern. Accordingly, it is possible to perform pattern segmentation of contour data by using only a semantic segmentation model without using an object detection model.

Next, the data of each of the classified and divided contours is converted into a data format by which dimensions can be easily calculated. An end point (feature point) normally necessary for the dimension measurement is a point at the uppermost end or the lowermost end of a contour, such as a vertex of the mask and a bottom of the trench, and four points, an upper end point, a lower end point, a left end point, and a right end point are required when the left and right ends are also included. Further, when each of the divided contours is viewed as one open curve, points at two ends (hereinafter referred to as a start point and an end point) can be defined. Accordingly, the feature points necessary for the minimum limit are six points, the top end point, the bottom end point, the left end point, the right end point, the start point, and the end point of a contour.

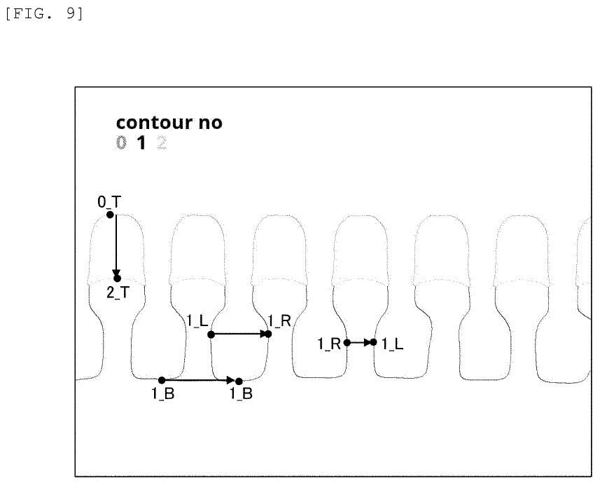

FIG. 8 is a diagram showing definitions of six types of feature points extracted from contours divided in Embodiment 1. Specifically, FIG. 8 shows positions of the above six feature points by taking the case of the contour 0 (320) as an example for a certain mask part included in the segmentation image. A coordinate axis in a vertical direction is defined as a y-axis, and a coordinate axis in a horizontal direction is an x-axis. The six feature points are a point T333 (a point which is a vertex T of the mask and has the smallest y coordinate), a point B334 (a point which is a bottom B of the mask and has the largest y coordinate), a point L335 (a point which is the leftmost point L of the mask and has the smallest x coordinate), a point R336 (a point which is the rightmost point R of the mask and has the largest x coordinate), a point S337 (which is an intersection of the contour 0 (320) and the contour 2 (322) and is also a start point S of the contour 0 (320) (a point having the smaller x coordinate of the two end points)), and a point E338 (which is an intersection of the contour 0 (320) and the contour 2 (322) and is also an end point E of the contour 0 (320) (a point having the larger x coordinate of the two end points) ). Depending on a shape of the contour 0 (320), a plurality of points among the six points may coincide with each other. In the example of FIG. 8, the point B334 coincides with the point S. In the inference step, the coordinates of the six feature points are obtained for each of the divided contours and stored in a file in the database 102.

During the measurement, the measurement direction of dimensions is fixed from the left to the right and from the top to the bottom, and the measurement start point and the measurement end point are each designated using the symbol “contour number feature point symbol”. The purpose of fixing the measurement direction is to determine whether the measurement target is within the contour based on a positional relation between the feature point symbols of the measurement start point and the measurement end point. That is, when the measurement start point is L and the measurement end point is R, the measurement direction is correct, and thus, a distance between inner portions of the contour is a measurement target. Conversely, when the measurement start point is R and the measurement end point is L, it is determined that a distance between outer portions of the contour, that is, a distance between two adjacent contours, is a measurement target. When the measurement start point and the measurement end point are the same symbol, it is determined that the measurement target is a distance between adjacent contours with the same number.

In addition to the exemplified contour 0, feature points are also extracted for the contour 1 and the contour 2. A case where the six feature points are extracted has been described, but the present disclosure is not limited thereto. Seven or more feature points may be defined and extracted.

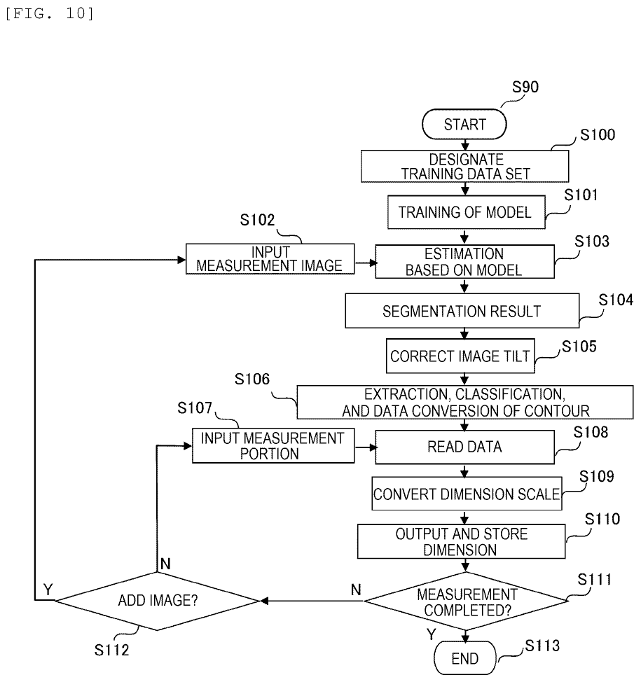

FIG. 9 is a diagram showing a method of designating a measurement portion in Embodiment 1. The measurement portion is designated by two points on a contour selected by the user. FIG. 9 shows an example of designating a mask height (0_T, 2_T), a trench bottom interval (1_B, 1_B), a maximum critical dimension (CD) (1_L, 1_R), and a minimum line width (1_R, 1_L). In the drawings, black circles indicate the coordinates of designated feature points, and arrows indicate measurement directions. In the above brackets, for example, the mask height (0_T, 2_T) indicates that the measurement is performed from the vertex 0_T of the mask toward the vertex 2_T of the substrate. The trench bottom interval (1_B, 1_B) indicates an interval between the adjacent trench bottoms. In this way, the measurement portion is designated by a combination of a contour number and an index (feature point symbol). When the width in the trench is measured as in the case of the maximum CD, the measurement start point is L and the measurement end point is R. However, when the width outside the trench, that is, the width in the line is measured as in the case of the minimum line width, the measurement start point is designated by R and the measurement end point is designated by L conversely. In this way, it is also easy to switch the measurement target between the trench and the line, and both the trench and the line can also be simultaneously measured. The obtained dimension is not a straight-line distance between two points but a difference in the x coordinate only for width, and a difference in the y coordinate only for height and depth. This is because the measurement dimension is measured parallel to the x axis or the y axis in terms of definition.

### Flow From Training to Measurement

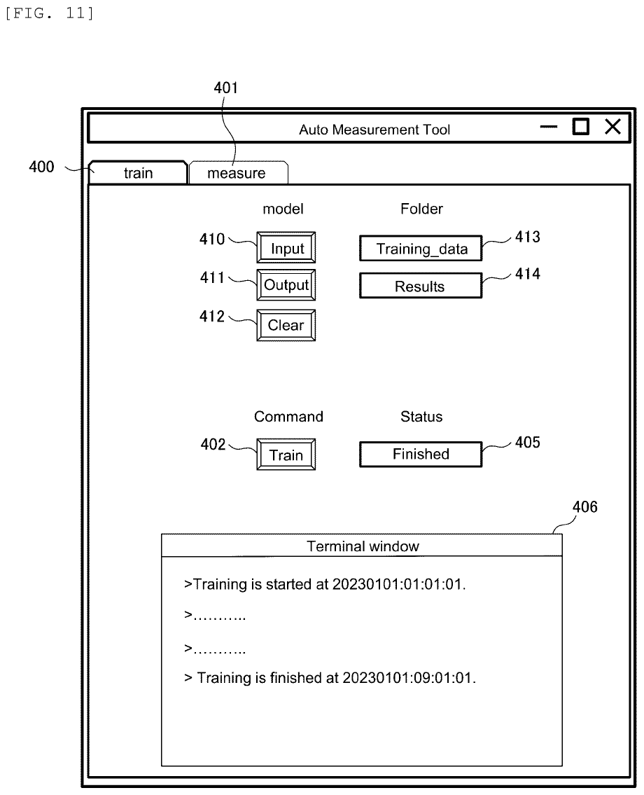

FIG. 10 is a flowchart showing an example of a processing procedure in the dimension measurement system. FIG. 10 shows a flowchart from the start of training to the measurement of a dimension of an input image. The training step corresponds to step S100 and step S101. The estimation step corresponds to step S102 to step S106, and the measurement step corresponds to step S107 to step S110.

First, the storage data 131 including processing conditions, imaging conditions, and training data sets is prepared in the server 101. The training data set is a set of annotation images (segmentation images in the present disclosure) that are color-coded for each region in addition to the cross-sectional SEM image that is input data. The training data set is designated from the input and output device 103 (step S100).

Next, the processor 116 causes the training unit 123 for the model to transfer the training data set from the database 102 and causes the training unit 123 to perform training of the model (step S101). The parameters of the trained model are stored in the database 102.

Next, in the estimation step, an image having dimensions to be measured is input from the input and output device 103 (step S102). The magnification of the input image is read from the database 102. The processor 116 passes the model and the parameters of the trained model from the database 102 to the inference unit 124 and passes the input image, and the inference unit 124 performs estimation (step S103) to obtain a segmentation image as an estimation result (step S104).

Next, the inference unit 124 corrects the tilt of the image so that a surface of a substrate is horizontal (step S105). Specifically, after determining contours, the inference unit 124 performs processing of correcting the tilt by rotating the segmentation image so that a surface of a cross-sectional structure in the segmentation image is horizontal to the image. Thereafter, the inference unit 124 classifies the contours determined from the segmentation image using a label, and converts a format of data of the classified contours (step S106). The inference unit 124 stores the determined feature point or an opposing distance between the contours in the database 102.

Next, in the measurement step, when the measurement portion designated by the user is input (step S107), the processor 116 reads necessary converted data from the database 102 (step S108), and passes the converted data to the dimension measurement unit 125. Further, the dimension measurement unit 125 determines a dimension by reading data necessary for measurement at a predetermined measurement portion from the database 102. The dimension measurement unit 125 calculates dimensions based on the designated measurement portion, segmentation image, and the like. The unit of the obtained dimensions is pixels, and thus the magnification stored in the database 102 is called up to convert the dimensions into actual dimensions (step S109).

The processor 116 also outputs the measured dimension result to the input and output device 103, and stores the numerical value and the image in the database 102 (step S110).

The processor 116 determines whether the necessary measurements have been completed (step S111), and if completed, ends the measurement (step S113). If the measurement is not completed and an image to be measured is to be added, the processing returns to step S102. If a measurement portion is to be added or changed, the processing returns to step S107 (step S112).

GUI Displayed on Measurement System during Training Step

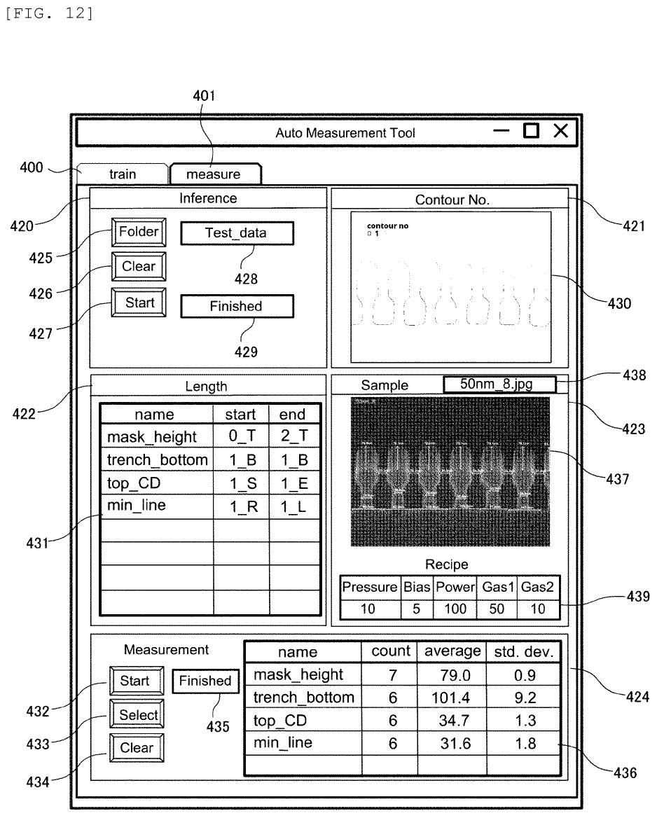

FIG. 11 is a diagram showing an example of a GUI screen displayed during the training of a model. The GUI screen is displayed on, for example, the input and output device 103. In the GUI screen shown in FIG. 11, a training screen used during training and a measurement screen used during the execution of the inference and measurement can be switched using tabs, and when a training tab 400 displayed as “train” is selected, the screen is displayed. A button group for instructing execution of the module and model training is arranged in an upper stage, and a terminal output screen (terminal window) 406 is arranged in a lower stage.

First, in the designation of the training data set (step S100 in FIG. 10), the user selects an input button (folder designation button) 410 to designate a folder in which the training data is stored, and designates the folder from a dialog that appears. The designated folder name is displayed in a folder name cell 413. Next, in order to designate a folder in which a trained model is to be stored after training, the user presses an output button (folder designation button) 411 to designate the folder from a dialog that appears. The designated folder name is displayed in a folder name cell 414. When the designated folder name is canceled, the user selects a clear button 412, and performs the operation of the input button 410 and the operation of the output button 411 again.

When the training of the model (step S101 in FIG. 10) is started, the user selects a training start button 402. A status display cell 405 indicating a status is displayed beside a training start button 202. When “Finished” is displayed in the status display cell 405, the training step of step S101 ends. The training takes time, and thus the progress of the training is output to a terminal output screen 406 and checked by the user as necessary.

GUI Displayed on Measurement System during Inference and Measurement Step

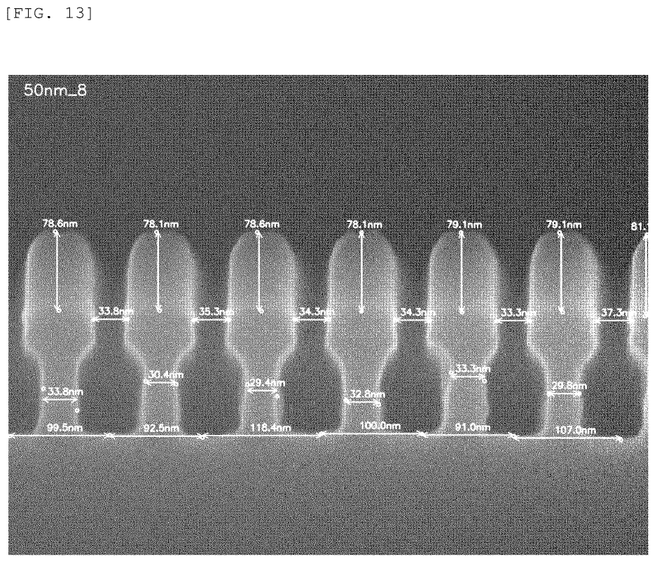

FIG. 12 is a diagram showing an example of a GUI screen displayed on the input and output device 103 when the inference and measurement step is performed. The GUI screen shown in FIG. 12 can be displayed by switching with the GUI screen shown in FIG. 11 using a tab. When a measurement tab 401 displayed as “measure” is selected, the screen shown in FIG. 12 is displayed. The screen includes an inference window 420, a contour window 421, a measurement portion setting window 422, a measurement result window 423, and a measurement value window 424.

In the measurement image input (step S102 in FIG. 10), the user selects a folder button 425 of the inference window 420, and selects a folder containing an image to be measured from a dialog that appears. A name of the selected folder is displayed in a right folder cell 428 on the right side. A clear button 426 is used to cancel the selection of a folder. In the estimation based on the model (step S103 in FIG. 10), when the user selects an inference start button 427, the inference is started, and when the inference is completed, a status is displayed in a status display cell 429 on the right side. During the inference, the output of the segmentation image that is the inference result (step S104 in FIG. 10), the image tilt correction (step S105 in FIG. 10), extraction, classification, and data conversion of the contour (step S106 in FIG. 10) are automatically performed.

At the same time as the completion of the inference, a contour diagram 430 divided for one measurement image is color-coded and displayed in the contour window 421. The user can check the correspondence relation between each contour number and color.

In the measurement portion input (step S107 in FIG. 10), the user inputs a name of the measurement portion, a measurement start point, and a measurement end point to a measurement portion cell 431 in the measurement portion setting window 422. Any method of assigning a name can be used. The measurement start point and the measurement end point are designated by the symbol “contour number_feature point symbol”. The example in which the user inputs the measurement start point and the measurement end point into the measurement portion cell 431 using the keyboard is shown in this drawing. However, the options are determined by the number of contour types and the number of feature point symbol types, and thus the input is implemented such that the measurement start point and the measurement end point are selected from a pull-down menu. Alternatively, a corresponding point on the contour diagram 430 is clicked with a mouse to detect a coordinate value thereof, and the symbol names of the measurement start point and the measurement end point may be automatically written on the measurement portion cell 431.

Next, the user selects a measurement start button 432 of the measurement value window 424 and starts the measurement. In data reading (step S108 in FIG. 10), data reading necessary for the measurement is performed on all the images included in the folder cell 428. After the dimension is calculated and conversion of the dimension scale is performed (step S109 in FIG. 10), the status is displayed in a status display cell 435.

In the dimension output and storage (step S110 in FIG. 10), the measurement results are stored in the database 102. When the display of results is performed, the user selects a select button 433 and selects a desired measurement image. When selected, a name of the image is displayed in a sample cell 438 in the measurement result window 423, and a measurement value-attached image 437 in which measurement values are assigned to the measurement image is displayed. In addition, a processing condition for the measurement image is called up from the database 102, and a processing recipe is displayed in a recipe display cell 439. At the same time, statistical values such as the detected number, an average value of dimensions, and a standard deviation are displayed in a measurement value display cell 436. When it is desired to display a result for another image, the user selects the select button 433 and reselects the measurement image. When it is desired to clear the display of the result, the user selects a clear button 434.

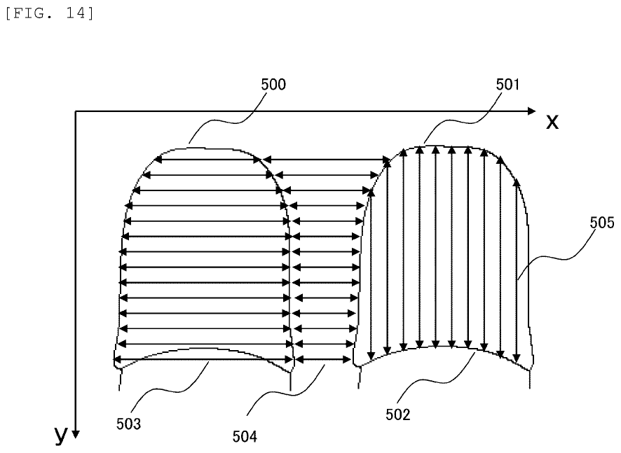

FIG. 13 is a diagram showing an example of measurement results. The measurement portions are indicated by a mask height (0_T, 2_T), a trench bottom interval (1_B, 1_B), a top CD (1_S, 1_E), and a minimum line width (1_R, 1_L). A white arrow representing a dimension is displayed such that the white arrow does not directly connect a start point and an end point, and passes through a midpoint between the start point and the end point in parallel to the coordinate axis. The measurement results of the mask height are 78.6 nm, 78.1 nm, 78.6 nm, 78.1 nm, 79.1 nm, and 79.1 nm from the left to the right in the drawing. The measurement results of the trench bottom interval are 99.5 nm, 92.5 nm, 118.4 nm, 100.0 nm, 91.0 nm, and 107.0 nm. The measurement results of the top CD are 33.8 nm, 35.3 nm, 34.3 nm, 34.3 nm, 33.3 nm, and 37.3 nm. The measurement results of the minimum line width are 33.8 nm, 30.4 nm, 29.4 nm, 32.8 nm, 33.3 nm, and 29.8 nm.

### Embodiment 2

The present embodiment describes a method of converting contour data into an opposing distance between the contours instead of the feature point in the processing of the contour data performed in Embodiment 1. The procedure until the classified contours are obtained is the same as that of Embodiment 1, and therefore the description thereof is omitted.

### Dimension Measurement Method

When measurement portions are determined based on a quantitative criterion such as “CD maximum value” or “CD value at Xo of trench depth” and are adopted as dimensions, it is necessary to determine all measurable CDs in combination with coordinates thereof for a certain portion. That is, it is necessary to determine the distance between two opposing coordinates inside a contour. Similarly, a distance between two adjacent contours is also necessary.

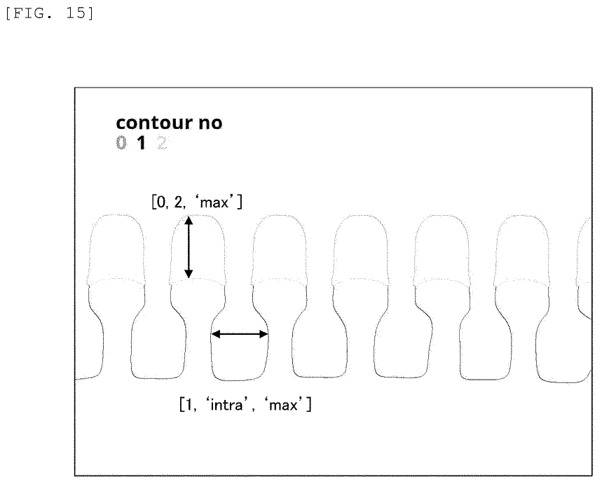

FIG. 14 is a diagram showing an opposing distance between contours extracted from the divided contours in Embodiment 2. Specifically, FIG. 14 is a diagram illustrating distances to be determined, taking the contours 0 (500 and 501) and the contour 2 (502) as examples. There are three types of distances to be determined, that is, an opposing distance 503 inside the contour 0, an opposing distance 504 between two adjacent contours 0, and an opposing distance 505 between the contour 0 and the contour 2, and the distances are determined along the coordinate axis. The same applies to a combination of other contours.

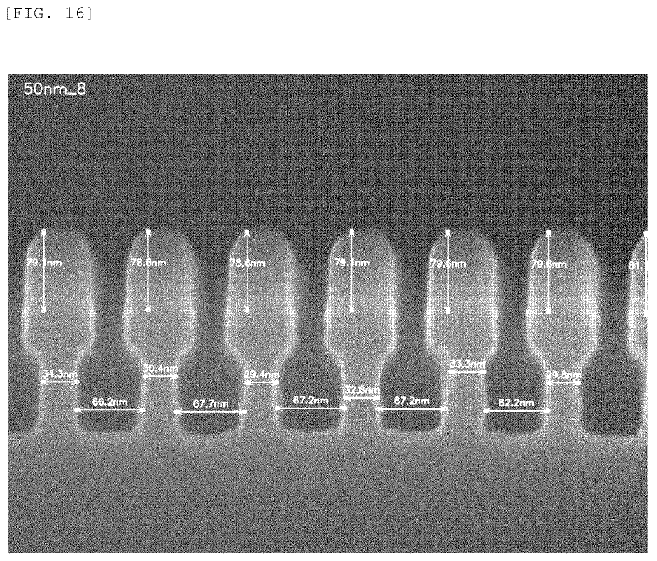

FIG. 15 is a diagram illustrating a method of designating a measurement portion. When the measurement portion relates to one type of contour, such as a maximum value of CD, three values called [contour number, intra or inter, index] are designated. The term “intra” indicates an opposing distance inside the contour, and the term “inter” indicates an opposing distance between two adjacent contours. The index includes a character string indicating a size such as a maximum or a minimum, or a numerical value indicating a position to be measured. Specifically, “max”, “min”, measurement position (values of height or depth), or the like can be designated as the index. The term “max” indicates the maximum length (maximum value), and the term “min” represents the minimum length (minimum value). For example, when the maximum CD is measured, a portion at which an internal distance of the contour 1 is maximum is measured, and therefore, the value 1 is designated as the contour number, the value “inter” is designated because it is an opposing distance inside one contour, and the value “max” is designated because it is the maximum value. The display [1, ‘intra’, ‘max’] and a double-headed arrow extending in the horizontal direction shown in FIG. 15 indicate a portion at which the maximum value of CD of a certain trench is measured.

In addition, when the measurement portion relates to two types of contours, such as the trench depth, three values called [first contour number, second contour number, index] are designated. The two contours are in no particular order. The term “max” or “min” can be designated as the index. For example, when the maximum mask thickness is measured, a portion at which the distance between the contour 0 and the contour 2 is maximum is measured, and therefore, 0 and 2 are designated as the contour numbers, and a value for “max” is designated as an index. The display [0, 2, ‘max’] and a double-headed arrow extending in the vertical direction in FIG. 15 indicate a portion at which the mask thickness is maximum in a certain mask. In either case, end points in the measurement are automatically determined based on the designated index.

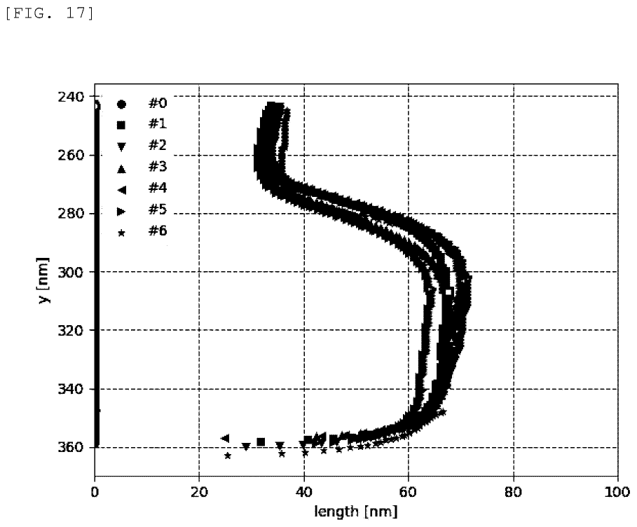

FIG. 16 is a diagram showing an example of measurement results. The measurement portions are indicated by a minimum line width ([1, ‘inter’, ‘min’]), a CD at 80% of the trench depth ([1, ‘intra’, 80]), and a maximum mask thickness ([0, 2, ‘max’]). A white arrow representing a dimension connects a start point and an end point and is drawn parallel to the coordinate axis. The measurement results of the minimum line width are 34.5 nm, 30.4 nm, 29.4 nm, 32.8 nm, 33.3 nm, and 29.8 nm. The measurement results of 80% of the trench depth are 66.2 nm, 67.7 nm, 67.2 nm, 67.2 nm, 62.2 nm were measured. The measurement results of the maximum mask thickness are 79.1 nm, 78.6 nm, 78.6 nm, 79.1 nm, 79.6 nm, and 79.6 nm.

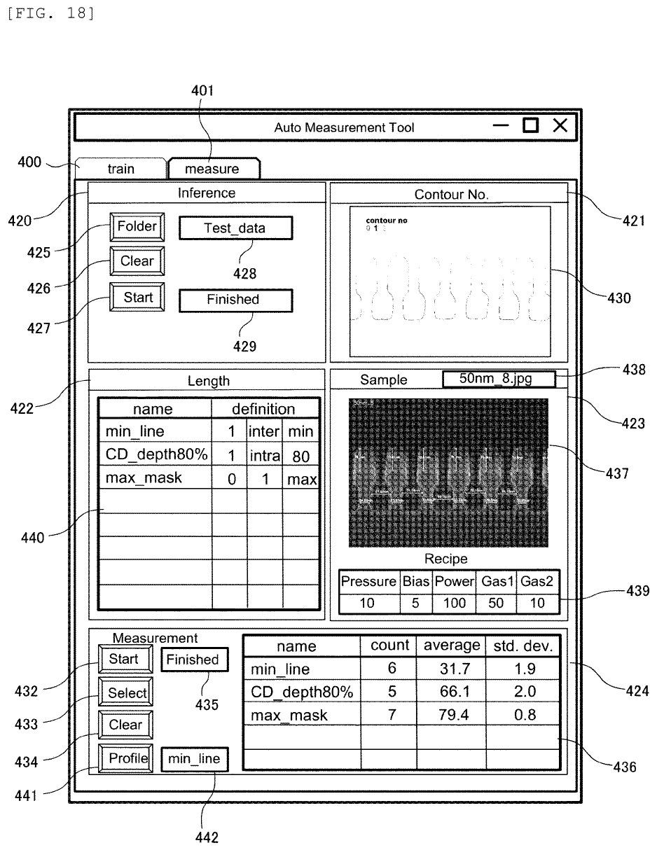

In the case of the present embodiment, it is also possible to perform a profile display of dimensions. FIG. 17 is a diagram showing an example of profile display results. Specifically, FIG. 17 shows the profile display results when the maximum CD ([1, ‘intra’, ‘max’]) is designated as an example. The profile display is based on measurement values acquired when the segmentation image includes six trenches. The vertical axis represents y coordinates, and the horizontal axis represents CD values. All the patterns of the six trenches are displayed in an overlapped manner, and a position at which the maximum value is obtained is displayed as an outlined symbol. According to this display, the inter-pattern variation of a trench shape can be grasped at a glance.

GUI during Inference and Measurement

The GUI screen during the training step is the same as that of Embodiment 1, and therefore is omitted. FIG. 18 is a diagram showing an example of a GUI screen displayed on the input and output device 103 when the inference and measurement step is performed. When the user selects the measurement tab 401 displayed as “measure”, the screen shown in FIG. 18 is displayed. The screen includes the inference window 420, the contour window 421, the measurement portion setting window 422, the measurement result window 423, and the measurement value window 424. The windows other than the measurement portion setting window 422 and the measurement value window 424 are the same as those in Embodiment 1, and therefore, description thereof is omitted. Further, the operation during the inference step is the same as that of Embodiment 1, and therefore, description thereof is omitted.

In the measurement portion input (step S107 in FIG. 10), the user inputs a name and a definition of the measurement portion to the recipe display cell 439 in the measurement portion setting window 422. Any method of assigning a name can be used. The three parameters used for the definition of the measurement portion are a set of the contour number, intra or inter, the value of the index, or the set of the first contour number, the second contour number, and the value of the index. In this drawing, the user inputs the contour number and the index into the recipe display cell 439 with a keyboard, and the input is implemented such that the contour number and the index are selected from a pull-down menu. Alternatively, only the contour number may be input by clicking the contour on the contour diagram 430 with a mouse.

Next, the user selects the measurement start button 432 of the measurement value window 424 and starts measurement. In data reading (step S108 in FIG. 10), data necessary for the measurement is read from all images contained in the folder cell 428. In addition, after the dimension is calculated and conversion of the dimension scale is performed (step S109 in FIG. 10), the status is displayed in a status display cell 435.

In the dimension output and storage (step S110 in FIG. 10), the measurement results are stored in the database 102. When the display of results is performed, the user selects the select button 433 and selects a desired measurement image. When selected, the measurement value-attached image 437 obtained by overwriting the measurement value in the measurement image is displayed in the measurement result window 423, and a name of the image is displayed in the sample cell 438. The processing conditions of the measurement image are called up from the database 102, and a processing recipe is displayed in the recipe display cell 439. At the same time, statistical values such as the detected number, the average value of dimensions, and the standard deviation are displayed in the measurement value display cell 436. When it is desired to display a result for another image, the user selects the select button 433 and reselects the measurement image. When it is desired to clear the display of the result, the user selects a clear button 434.

Further, when it is desired to display a profile, the user selects the profile button 441 and selects a measurement portion desired to be displayed from a dialog that appears. The name of the selected measurement portion is displayed in the measurement portion cell 442, and profile results corresponding to FIG. 17 are displayed in the measurement result window 423 instead of the measurement value-attached image 437 obtained by overwriting the measurement value on the input image. When it is desired to display a profile of another measurement portion, the user selects the profile button 441 and reselects the measurement portion.

### Functions and Effects

When the semantic segmentation model is utilized using machine learning, a shape can be grasped without limiting a shape included in a cross-sectional image. In addition, it is adopted that the contours are classified, and the feature point extracted in advance for each contour or the opposing distance between contours is utilized as a dimension measurement portion. In the present disclosure, dimension measurement for any portion can be implemented without system correction.

The invention is not limited to the above embodiments, and includes various modifications and equivalent configurations within the scope of the appended claims. For example, the embodiment is described in detail for easy understanding of the invention, and the invention is not necessarily limited to those including all the configurations described above. A part of a configuration of one embodiment can be replaced with a configuration of another embodiment. A configuration of one embodiment may also be added to a configuration of another embodiment. Another configuration may be added to a part of a configuration of each embodiment, and a part of the configuration of each embodiment may be deleted or replaced with another configuration.

A part or all of the above-described configurations, functions, processing units, processing methods, and the like may be implemented by hardware by, for example, designing with an integrated circuit, or may be implemented by software by, for example, a processor interpreting and executing a program for implementing each function. Information such as a program, a table, and a file for implementing each function can be stored in a storage device such as a memory, a hard disk, and a solid state drive (SSD), or a recording medium such as an integrated circuit (IC) card, an SD card, and a digital versatile disc (DVD).

Control lines and information lines considered to be necessary for descriptions are shown, and not all control lines and information lines necessary for implementation are shown. Actually, it may be considered that almost all the configurations are connected to one another.

Aspects that may be contents of the invention will be described below, but the invention is not limited thereto.

### Aspect 1

A dimension measurement device for measuring, based on a cross-sectional image of a semiconductor device having a repeating pattern, a dimension of the semiconductor device, the dimension measurement device including:
a processor; and
a memory, in which
the memory stores a dimension measurement program causing the processor to function as
   a training unit in which a semantic segmentation model is implemented,
   an inference unit configured to determine, based on a segmentation image output by the training unit in response to an input image, contours classified using label information of the segmentation image, and to determine, based on the contours, a feature point satisfying a predetermined criterion or an opposing distance between contours, and
   a dimension measurement unit configured to measure a dimension of a predetermined measurement portion using data determined by the inference unit.

### Aspect 2

The dimension measurement device according to aspect 1, in which
the predetermined measurement portion is designated by two points on the contour selected by a user.

### Aspect 3

The dimension measurement device according to aspect 1 or 2, in which
the feature point includes any one of a top end point, a bottom end point, a left end point, a right end point, a start point, and an end point of the contour.

### Aspect 4

The dimension measurement device according to any one of aspects 1 to 3, in which
the predetermined measurement portion is designated by a combination of a contour number and an index.

### Aspect 5

The dimension measurement device according to any one of aspects 1 to 4, in which
the index includes a character string indicating a size such as a maximum or a minimum, or a numerical value indicating a position to be measured.

### Aspect 6

The dimension measurement device according to any one of aspects 1 to 5, in which
after the contour is determined, processing of correcting a tilt by rotating the segmentation image is performed to cause a surface of a cross-sectional structure in the segmentation image to be horizontal to the image.

### Aspect 7

The dimension measurement device according to any one of aspects 1 to 6, in which
the cross-sectional image is a cross-sectional SEM image or a TEM image.

### Aspect 8

The dimension measurement device according to any one of aspects 1 to 7, further including:
a database configured to store the feature point or the opposing distance between the contours which is determined by the inference unit, in which
the dimension measurement unit determines a dimension by reading data necessary for the measurement at the predetermined measurement portion from the database.

### Aspect 9

A dimension measurement system including:
the dimension measurement device according to any one of aspects 1 to 8;
a processing device configured to process the semiconductor device; and
an evaluation device configured to evaluate the semiconductor device, in which
the dimension measurement device measures a dimension of the semiconductor device based on a cross-sectional image of the semiconductor device outputted by the evaluation device.

### Aspect 10

A dimension measurement method for measuring, based on a cross-sectional image of a semiconductor device having a repeating pattern, a dimension of the semiconductor device, the dimension measurement method including:
a step of training a semantic segmentation model;
a step of determining, based on a segmentation image obtained by performing inference on an input image using the trained semantic segmentation model, contours classified using label information of the segmentation image, and determining, based on the contours, a feature point satisfying a predetermined criterion or a distance between contours; and
a step of measuring a dimension of a predetermined measurement portion using the determined data during measurement.

### Aspect 11

The dimension measurement method according to aspect 10, in which
the predetermined measurement portion is designated by two points on the contour selected by a user.

### Aspect 12

The dimension measurement method according to aspect 10 or 11, in which
the feature point includes any one of a top end point, a bottom end point, a left end point, a right end point, a start point, and an end point of the contour.

### Aspect 13

The dimension measurement method according to any one of aspects 10 to 12, in which
a user designates the predetermined measurement portion by a combination of a contour number and an index.

### Aspect 14

The dimension measurement method according to any one of aspects 10 to 13, in which
the index includes a character string indicating a size such as a maximum or a minimum, or a numerical value indicating a position to be measured.

### Aspect 15

The dimension measurement method according to any one of aspects 10 to 14, further including:
a step of performing, after the contour is determined, processing of correcting a tilt by rotating the segmentation image to cause a surface of a cross-sectional structure in the segmentation image to be horizontal to the image.

### Aspect 16

The dimension measurement method according to any one of aspects 10 to 15, in which
the cross-sectional image is a cross-sectional SEM image or a TEM image.

### Aspect 17

The dimension measurement method according to any one of aspects 10 to 16, in which
the determination step further includes a step of storing the determined feature point or the determined opposing distance between the contours, and
in the step of measuring the dimension, a dimension is determined by reading data necessary for the measurement at the predetermined measurement portion.

### Aspect 18

A dimension measurement system including:
a dimension measurement device performing the dimension measurement method according to any one of aspects 10 to 17;
a processing device configured to process the semiconductor device; and
an evaluation device configured to evaluate the semiconductor device, wherein
the dimension measurement device measures a dimension of the semiconductor device based on a cross-sectional image of the semiconductor device outputted by the evaluation device.

### Reference Signs List

30: neural network
100: evaluation device
101: server
102: database
103: input and output device (terminal or PC)
110: dimension measurement system
111: processing device
115: interface
116: processor
117: ROM
118: RAM
123: training unit
124: inference unit
125: dimension measurement unit
126: storage
127: annotation tool
128: dimension measurement software
130: dimension measurement result
131: storage data
132: designation data
300: background
301: mask
302: substrate
310: background region
311: mask region
312: substrate region
320: contour 0
321: contour 1
322: contour 2
333: point T
334: point B
335: point L
336: point R
337: point S
338: point E
400: training tab
401: measurement tab
402: training start button
405: status display cell
406: terminal output screen (terminal window)
410: input button (folder designation button)
411: output button (folder designation button)
412: clear button
413: folder name cell
414: folder name cell
420: inference window
421: contour window
422: measurement portion setting window
423: measurement result window
424: measurement value window
425: folder button
426: clear button
427: inference start button
428: folder cell
429: status display cell
430: contour diagram
431: measurement portion cell
432: measurement start button
433: select button
434: clear button
435: status display cell
436: measurement value display cell
437: measurement value-attached image
438: sample cell
439: recipe display cell
440: measurement portion definition cell
441: profile button
442: measurement portion cell
500: contour 0
501: contour 0
502: contour 2
503: opposing distance inside contour 0
504: opposing distance between two contours 0
505: opposing distance between contour 0 and contour 2

1. A dimension measurement device for measuring, based on a cross-sectional image of a semiconductor device having a repeating pattern, a dimension of the semiconductor device, the dimension measurement device comprising:
a processor; and
a memory, wherein
the memory stores a dimension measurement program causing the processor to function as
a training unit in which a semantic segmentation model is implemented,
an inference unit configured to determine, based on a segmentation image output by the training unit in response to an input image, contours classified using label information of the segmentation image, and to determine, based on the contours, a feature point satisfying a predetermined criterion or an opposing distance between contours, and
a dimension measurement unit configured to measure a dimension of a predetermined measurement portion using data determined by the inference unit.

2. The dimension measurement device according to claim 1, wherein
the predetermined measurement portion is designated by two points on the contour selected by a user.

3. The dimension measurement device according to claim 1, wherein
the feature point includes any one of a top end point, a bottom end point, a left end point, a right end point, a start point, and an end point of the contour.

4. The dimension measurement device according to claim 1, wherein
the predetermined measurement portion is designated by a combination of a contour number and an index.

5. The dimension measurement device according to claim 4, wherein
the index includes a character string indicating a size such as a maximum or a minimum, or a numerical value indicating a position to be measured.

6. The dimension measurement device according to claim 1, wherein
after the contour is determined, processing of correcting a tilt by rotating the segmentation image is performed to cause a surface of a cross-sectional structure in the segmentation image to be horizontal to the image.

7. The dimension measurement device according to claim 1, wherein
the cross-sectional image is a cross-sectional SEM image or a TEM image.

8. The dimension measurement device according to claim 1, further comprising:
a database configured to store the feature point or the opposing distance between the contours which is determined by the inference unit, wherein
the dimension measurement unit determines a dimension by reading data necessary for the measurement at the predetermined measurement portion from the database.

9. A dimension measurement system comprising:
the dimension measurement device according to claim 1;
a processing device configured to process the semiconductor device; and
an evaluation device configured to evaluate the semiconductor device, wherein
the dimension measurement device measures a dimension of the semiconductor device based on a cross-sectional image of the semiconductor device outputted by the evaluation device.

10. A dimension measurement method for measuring, based on a cross-sectional image of a semiconductor device having a repeating pattern, a dimension of the semiconductor device, the dimension measurement method comprising:
a step of training a semantic segmentation model;
a step of determining, based on a segmentation image obtained by performing inference on an input image using the trained semantic segmentation model, contours classified using label information of the segmentation image, and determining, based on the contours, a feature point satisfying a predetermined criterion or an opposing distance between contours; and
a step of measuring a dimension of a predetermined measurement portion using the determined data during measurement.

11. The dimension measurement method according to claim 10, wherein
the predetermined measurement portion is designated by two points on the contour selected by a user.

12. The dimension measurement method according to claim 10, wherein
the feature point includes any one of a top end point, a bottom end point, a left end point, a right end point, a start point, and an end point of the contour.

13. The dimension measurement method according to claim 10, wherein
a user designates the predetermined measurement portion by a combination of a contour number and an index.

14. The dimension measurement method according to claim 13, wherein
the index includes a character string indicating a size such as a maximum or a minimum, or a numerical value indicating a position to be measured.

15. The dimension measurement method according to claim 10, further comprising:
a step of performing, after the contour is determined, processing of correcting a tilt by rotating the segmentation image to cause a surface of a cross-sectional structure in the segmentation image to be horizontal to the image.

16. The dimension measurement method according to claim 10, wherein
the cross-sectional image is a cross-sectional SEM image or a TEM image.

17. The dimension measurement method according to claim 10, wherein
the determination step further includes a step of storing the determined feature point or the determined opposing distance between the contours, and
in the step of measuring the dimension, a dimension is determined by reading data necessary for the measurement at the predetermined measurement portion.

18. (canceled)

19. A dimension measurement system comprising:
a dimension measurement device comprising:
a processor; and
a memory, wherein
the memory stores a dimension measurement program causing the processor to function as
a training unit in which a semantic segmentation model is implemented,
an inference unit configured to determine, based on a segmentation image output by the training unit in response to an input image, contours classified using label information of the segmentation image, and to determine, based on the contours, a feature point satisfying a predetermined criterion or an opposing distance between contours, and
a dimension measurement unit configured to measure a dimension of a
predetermined measurement portion using data determined by the inference unit;
a processing device configured to process the semiconductor device; and
an evaluation device configured to evaluate the semiconductor device, wherein
the predetermined measurement portion is designated by two points on the contour selected by a user, and
the dimension measurement device measures a dimension of the semiconductor device based on a cross-sectional image of the semiconductor device outputted by the evaluation device.

20. The dimension measurement system according to claim 19, wherein
the feature point includes any one of a top end point, a bottom end point, a left end point, a right end point, a start point, and an end point of the contour.

21. The dimension measurement system according to claim 19, wherein
the predetermined measurement portion is designated by a combination of a contour number and an index.
